(19) United States
(12) Patent Application Publication
(10) Pub. No.: US 2024/0234588 A1
(43) Pub. Date: Jul. 11, 2024

(54) SELF-BIASED MO/N-4H-SIC SCHOTTKY BARRIERS AS HIGH-PERFORMANCE ULTRAVIOLET PHOTODETECTORS

(71) Applicant: University of South Carolina, Columbia, SC (US)

(72) Inventor: Krishna C. Mandal, Columbia, SC (US)

(73) Assignee: University of South Carolina, Columbia, SC (US)

(21) Appl. No.: 18/506,413

(22) Filed: Nov. 10, 2023

Related U.S. Application Data
(60) Provisional application No. 63/479,379, filed on Jan. 11, 2023.

(51) Int. Cl. H01L 29/872; H01L 29/16; H01L 29/66

(52) U.S. Cl. CPC H01L 29/872; H01L 29/1608; H01L 29/6606

(57) ABSTRACT

Described herein are methods of making, as well as self-biased UV photodetectors used to design self-powered UV sensors for harsh environment applications, e.g., advanced nuclear reactors and space missions, to provide wide bandgap semiconductors as high-efficiency self-biased UV photodetectors.

### STATEMENT REGARDING FEDERALLY SPONSORED RESEARCH

This invention was made with government support under Grant Number DE-NE0008662, awarded by the DOE. The government has certain rights in the invention.

### TECHNICAL FIELD

The subject matter disclosed herein is generally directed self-biased UV photodetectors used to design self-powered UV sensors for harsh environment applications, e.g., advanced nuclear reactors and space missions, to provide wide bandgap semiconductors as high-efficiency self-biased UV photodetectors, as well as methods of making same.

### BACKGROUND

Development of scintillator materials that can sustain high temperatures and radiation background are in the rise as there is a high demand in field applications such as monitoring radiation near nuclear reactor cores, in high energy astrophysics, medical imaging, and nuclear non-proliferation. See, Y. Saito, S. Gunji, T. Nakamori, T. Mihara, D. Yonetoku, T. Sawano, S. Kurosawa and S. Kodaira, “Irradiation tests of silicon photomultipliers for use in space,” IEEE Trans. Nucl. Sci., vol. 70, no. 2, pp. 150-155, February 2023, doi: 10.1109/TNS.2022.3162788, J. D. Wrbaneck and S. Y. Wrbaneck, “Space Radiation and Impact on Instrumentation Technologies,” Glenn Research Center, Cleveland, OH, USA, NASA/TP-2020-220002, January 2020, and Y. Xu, Y. Qi, Q. Qian, J. Chen, Z. Yang and K. Wang. “Backside Illuminated 3-D Photosensitive Thin-Film Transistor on a Scintillating Glass Substrate for Indirect-Conversion X-Ray Detection,” IEEE Electron. Dev. Lett., vol. 41, no. 8, pp. 1209-1212. June 2020, doi: 10.1109/LED.2020.3001922. Most scintillators that detect high energy gamma rays with prompt timing response, emit in the ultraviolet region. See, C. Piemonte, F. Acerbi, A. Ferri, A. Gola, G. Patrnoster, V. Regazzoni, G. Zappala and N. Zorzi, “Performance of NUV-HD Silicon Photomultiplier Technology,” IEEE Trans. Electron. Devices, vol. 63, no. 3, pp. 1111-1116, March 2016, doi: 10.1109/TED.2016.2516641.

The primary bottleneck in the application of scintillator detectors in harsh environments is the lack of availability of photodetectors or photomultiplier tubes (PMTs) that can detect the scintillating radiations and withstand high temperatures and radiation background. See, A. Datta, R. Toufanian, W. Zhang. P. S. Halasyamani and S. Motakef, “Radiation hard gallium oxide scintillators for high count rate radiation detection,” Opt. Mater., vol. 134, December 2022, Art. no. 113115, doi: 10.1016/j.optmat.2022.113115 and P. Bhattacharya, C. Brown, C. Sosa, M. Wart, S. Miller, C. Brecher and V. V. Nagarkar, “Tl₂ZrCl₆ and Tl₂HfCl₆ Intrinsic Scintillators for Gamma Rays and Fast Neutron Detection,” IEEE Trans. Nucl. Sci., vol. 67, no. 6, pp. 1032-1034, June 2020, doi: 10.1109/TNS.2020.2997659. Moreover, PMTs require high operating voltages and are incompatible with radio imaging modalities such as magnetic resonance imaging (MRI) where strong magnetic fields are involved. See, S. Kasap and Z. Kabir, “X-Ray Detectors,” in Springer Handbook of Semiconductor Devices, M. Rudan, R. Brunetti and S. Reggiani, Eds., Cham, Springer, 2022, pp. 747-776. 4H-SiC UV detectors are compact, low power consuming, and high gain devices in high temperature and high radiation background, and hence, finds immense applications as sensors in harsh-environment applications including applications in advanced nuclear reactors. Indeed, self-biased 4H-SiC UV detectors are much sought-after devices for NASA or DOD's space missions where carrying power supplies for biasing creates logistics issues.

Accordingly, it is an object of the present disclosure to provide new device structures via the unexplored potential of wide bandgap semiconductors (e.g., GaN, Ga₂O₃, etc.) as high-gain self-biased UV photodetectors.

Citation or identification of any document in this application is not an admission that such a document is available as prior art to the present disclosure.

### SUMMARY

The above objectives are accomplished according to the present disclosure by providing in one aspect a vertical Schottky diode. The vertical Schottky diode may include at least one semi-transparent metal anode contact deposited on at least one silicon face of at least one n-type 4H-SiC epilayer, at least one 4H-SiC buffer layer affixed to the at least one n-type 4H-SiC epilayer, at least one n-type 4H-SiC bulk layer affixed to the at least one 4H-SiC buffer layer, at least one cathode affixed to the at least one 4H-SiC buffer layer on a side opposite the at least one n-type 4H-SiC bulk layer. Further, the effective doping concentration of the at least one semi-transparent metal anode contact deposited on the at least one n-type 4H-SiC epilayer may be 10\hat{ }¹⁴ cm\hat{ }⁻³. Yet again, the at least one n-type 4H-SiC epilayer may be substantially 20 μm in thickness. Yet still, the vertical Schottky diode may be incorporated into at least one self-biased ultraviolet photovoltaic cell. Further again, the vertical Schottky diode may be incorporated into at least one self-powered ultraviolet sensor. Moreover, the at least one self-powered ultraviolet sensor may be incorporated into at least one nuclear reactor or at least one space craft. Still further, the vertical Schottky diode may have a built-in voltage of 2.48 V measured from capacitance-voltage characteristics with a test frequency of 1 MHz. Further again, the vertical Schottky diode may have a hole diffusion length of 22.8 μm calculated using a drift-diffusion model applied to alpha radiation response of the vertical Schottky. Even further, the vertical Schottky diode may have a charge collection efficiency of substantially 70% when exposed to 5486 keV alpha particles and a current gain at 0 V applied bias. Still yet further, the at least one semi-transparent metal anode contact may comprise molybdenum and the at least one cathode may comprise nickel.

In a further aspect, the current disclosure may provide a method for making a vertical Schottky diode. The method may include depositing, via hot-wall chemical vapor deposition, at least one semi-transparent metal anode onto at least one silicon face of at least one n-type 4H-SiC epitaxial layer, forming at least one 4H-SiC buffer layer attached to the at least one n-type 4H-SiC epitaxial layer, forming at least one n-type 4H-SiC bulk layer attached to the at least one 4H-SiC buffer layer, and forming at least one cathode affixed to a side of the n-type 4H-SiC bulk layer opposite the at least one n-type 4H-SiC buffer layer. Further, the effective doping concentration of the at least one semi-transparent metal anode contact deposited on the at least one n-type 4H-SiC epitaxial layer may be 10\hat{ }¹⁴ cm\hat{ }⁻³. Yet again, the at least one n-type 4H-SiC epitaxial may be substantially 20 μm in thickness. Further again, the vertical Schottky diode may be incorporated into at least one self-biased ultraviolet photovoltaic cell. Still further, the vertical Schottky diode may be incorporated into at least one self-powered ultraviolet sensor. Again still, the at least one self-powered ultraviolet sensor may be incorporated into at least one nuclear reactor or at least one space craft. Moreover again, the vertical Schottky diode may be configured to have a built-in voltage of 2.48 V measured from capacitance-voltage characteristics with a test frequency of 1 MHz. Further yet, the vertical Schottky diode may be configured to have a hole diffusion length of 22.8 μm calculated using a drift-diffusion model applied to alpha radiation response of the vertical Schottky. Yet again still, the vertical Schottky diode may be configured to have a charge collection efficiency of substantially 70% when exposed to 5486 keV alpha particles and a current gain at 0 V applied bias. Again further, the at least one semi-transparent metal anode contact may be configured to comprise molybdenum and the at least one cathode may be configured to comprise nickel.

These and other aspects, objects, features, and advantages of the example embodiments will become apparent to those having ordinary skill in the art upon consideration of the following detailed description of example embodiments.

### BRIEF DESCRIPTION OF THE DRAWINGS

An understanding of the features and advantages of the present disclosure will be obtained by reference to the following detailed description that sets forth illustrative embodiments, in which the principles of the disclosure may be utilized, and the accompanying drawings of which:

FIG. 1 shows at: (a) Schematic diagram of the Mo/n-4H-SiC epitaxial SBD structure and (b) Photograph of an 8 mm×8 mm detector mounted on a printed circuit board (PCB) exposed to an UV LED.

FIG. 2 shows at: (a) Variation of current density with bias for a Mo/4H-SiC epitaxial SBD and (b) C-V characteristic (left y-axis) and the Mott-Schottky plot (A²/C² vs V, A being the anode area, right y-axis).

FIG. 3 shows at: (a) Pulse height spectrum in self-biased mode obtained using the Mo/4H-SiC SBD with and exposed to a ²⁴¹Am radioisotope and (b) Variation of CCE and its various components as a function of the applied reverse bias.

FIG. 4 shows at: (a) I-V characteristics under dark and UV (365 nm) illumination of a Mo/4H-SiC SBD and (b) Absolute forward current (left-y) and the output power (right-y) under UV illumination.

The figures herein are for illustrative purposes only and are not necessarily drawn to scale.

### DETAILED DESCRIPTION OF THE EXAMPLE EMBODIMENTS

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is also not expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range is expressed, a further embodiment includes from the one particular value and/or to the other particular value. The recitation of numerical ranges by endpoints includes all numbers and fractions subsumed within the respective ranges, as well as the recited endpoints. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g., the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the singular forms “a”, “an”, and “the” include both singular and plural referents unless the context clearly dictates otherwise.

As used herein, “about,” “approximately,” “substantially,” and the like, when used in connection with a measurable variable such as a parameter, an amount, a temporal duration, and the like, are meant to encompass variations of and from the specified value including those within experimental error (which can be determined by e.g. given data set, art accepted standard, and/or with e.g. a given confidence interval (e.g. 90%, 95%, or more confidence interval from the mean), such as variations of +/−10% or less, +/−5% or less, +/−1% or less, and +/−0.1% or less of and from the specified value, insofar such variations are appropriate to perform in the disclosure. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

The term “optional” or “optionally” means that the subsequent described event, circumstance or substituent may or may not occur, and that the description includes instances where the event or circumstance occurs and instances where it does not.

As used interchangeably herein, the terms “sufficient” and “effective,” can refer to an amount (e.g. mass, volume, dosage, concentration, and/or time period) needed to achieve one or more desired and/or stated result(s). For example, a therapeutically effective amount refers to an amount needed to achieve one or more therapeutic effects.

As used herein, “tangible medium of expression” refers to a medium that is physically tangible or accessible and is not a mere abstract thought or an unrecorded spoken word. “Tangible medium of expression” includes, but is not limited to, words on a cellulosic or plastic material, or data stored in a suitable computer readable memory form. The data can be stored on a unit device, such as a flash memory or CD-ROM or on a server that can be accessed by a user via, e.g. a web interface.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment”, “an embodiment,” “an example embodiment,” means that a particular feature, structure or characteristic described in connection with the embodiment is included in at least one embodiment of the present disclosure. Thus, appearances of the phrases “in one embodiment,” “in an embodiment,” or “an example embodiment” in various places throughout this specification are not necessarily all referring to the same embodiment but may. Furthermore, the particular features, structures or characteristics may be combined in any suitable manner, as would be apparent to a person skilled in the art from this disclosure, in one or more embodiments. Furthermore, while some embodiments described herein include some, but not other features included in other embodiments, combinations of features of different embodiments are meant to be within the scope of the disclosure. For example, in the appended claims, any of the claimed embodiments can be used in any combination.

All patents, patent applications, published applications, and publications, databases, websites, and other published materials cited herein are hereby incorporated by reference to the same extent as though each individual publication, published patent document, or patent application was specifically and individually indicated as being incorporated by reference.

### Kits

Any of the high-performance ultraviolet photodetectors can be presented as a combination kit. As used herein, the terms “combination kit” or “kit of parts” refers to the compounds, compositions, formulations, and any additional components that are used to package, sell, market, deliver, and/or provide the photodetectors. Such additional components include, but are not limited to packaging, syringes, blister packages, bottles, and the like. When one or more of the compounds, compositions, formulations, and any additional components in the kit are administered simultaneously, the combination kit can contain the high-performance ultraviolet photodetector in a single embodiment or in separate embodiments. When the compounds, compositions, formulations, and any additional components described herein or a combination thereof and/or kit components are not provided simultaneously, the combination kit can contain each part or other component in separate embodiments. The separate kit components can be contained in a single package or in separate packages within the kit.

In some embodiments, the combination kit also includes instructions printed on or otherwise contained in a tangible medium of expression. The instructions can provide information regarding the high-performance ultraviolet photodetectors, safety information regarding the content of the compounds and compositions forming the high-performance ultraviolet photodetectors, information regarding usage, indications for use, and/or recommended applications for the high-performance ultraviolet photodetectors. In some embodiments, the instructions can provide directions and protocols for forming the high-performance ultraviolet photodetectors, such as any of the methods described in greater detail elsewhere herein.

We report high current gain of ˜10\hat{ }⁶ observed in metal/4H-SiC Schottky diodes (SBDs) in self-biased mode when exposed to a 1.5 mW ultraviolet (UV) light emitting diode (LED) emitting at 365 nm with a spectral line half width of 15 nm.

Such high performing self-biased UV photovoltaic cells are poised to address the outstanding problem of designing self-powered UV sensors for harsh environment applications in advanced nuclear reactors and space missions. The vertical Schottky diode has been fabricated by depositing semi-transparent metal anode contact on 20 μm n-type 4H-SiC epilayer with an effective doping concentration of 10\hat{ }14 cm\hat{ }⁻³. The SBDs demonstrated a built-in voltage of 2.48 V as measured from capacitance-voltage characteristics with a test frequency of 1 MHZ. A hole diffusion length of 22.8 μm was calculated using a drift-diffusion model applied to alpha radiation response of the SBDs. Such high built-in voltage and hole diffusion length led to the excellent charge collection efficiency of 70% when exposed to 5486 keV alpha particles and the large current gain at 0 V applied bias (self-biased mode). The results revealed for the first time the unexplored potential of wide bandgap semiconductors as high-efficiency self-biased UV photodetectors.

We report for the first time, fabrication of high current gain metal/4H-SiC Schottky diodes (SBDs) in self-biased mode when exposed to an ultraviolet (UV) light emitting diode (LED) emitting at 365 nm with a sharp spectral line half width. The Schottky diode has been fabricated by depositing semi-transparent metal anode on n-type 4H-SiC epilayers with an effective doping concentration of 10\hat{ }14 cm\hat{ }⁻³. The SBDs demonstrated a very high built-in voltage as measured from capacitance-voltage characteristics with a test frequency of 1 MHZ. A very high hole diffusion length was calculated using a drift-diffusion model applied to alpha radiation response of the SBDs. Such high built-in voltage and hole diffusion length led to the excellent charge collection efficiency of 70% when exposed to 5486 keV alpha particles and the large current gain at 0 V applied bias (self-biased mode).

The 4H polytype of silicon carbide or 4H-SiC is a wide bandgap (3.27 eV) semiconductor that is radiation hard, solar blind, chemically inert, mechanically robust, and economical. See, S. K. Chaudhuri and K. C. Mandal, “Radiation Detection Using n-Type 4H-SiC Epitaxial Layer Surface Barrier Detectors,” in Advanced Materials for Radiation Detection, K. Iniewski (ed.) Cham., Springer, August 2022, pp. 183-209, I. Capan, T. Brodar, R. Bernat, Ž. Pastuović, T. Makino, T. Ohsima, J. D. Gouveia and J. Coutinho, “M-center in 4H-SiC: Isothermal DLTS and first principles modeling studies,” J. Appl. Phys., vol. 130, September 2021, Art. no. 125703, doi: 10.1063/5.0064958, and J. W. Kleppinger, S. K. Chaudhuri, O. Karadavut, R. Nag. D. L. Watson, D. S. McGregor and K. C. Mandal, “Deep-Level Transient Spectroscopy and Radiation Detection Performance Studies on Neutron Irradiated 250-μm Thick 4H-SiC Epitaxial Layers,” IEEE Trans. Nucl. Sci., vol. 69, no. 8, pp. 1972-1978, August 2022, doi: 10.1109/TNS.2022.3168789. 4H-SiC electronic devices and sensors have demonstrated very high breakdown voltages and are operable at extremely high temperatures for prolonged periods. S. Bodie, G. Lioliou and A. M. Barnett, “Hard X-ray and γ-ray spectroscopy at high temperatures using a COTS SiC photodiode,” Nucl. Instrum. Meth. Phys. Res. A, vol. 985, January 2021, Art no. 164663, doi: 10.1016/j.nima.2020.164663, J. W. Kleppinger, S. K. Chaudhuri, O. Karadavut and K. C. Mandal, “Role of deep levels and barrier height lowering in current-flow mechanism in 150 μm thick epitaxial n-type 4H-SiC Schottky barrier radiation detectors,” Appl. Phys. Lett., vol. 119, August 2021, Art. no. 063502, doi: 10.1063/5.0064036, P. G. Neudeck, D. J. Spry, L. Chen, N. F. Prokop and M. J. Krasowski, “Demonstration of 4H-SiC digital integrated circuits above 800° C.,” IEEE Electron. Dev. Lett., vol. 38, no. 8, pp. 1082-1085, August 2017, doi: 10.1109/LED.2017.2719280, and S. Das, T. Isaacs-Smith, A. Ahyi, M. A. Kuroda and S. Dhar, “High temperature characteristics of nitric oxide annealed p-channel 4H-SiC metal oxide semiconductor field effect transistors,” J. Appl. Phys., vol. 130, December 2021, Art. no. 225701, doi: 10.1063/5.0073523.

The wide bandgap, high melting point (>3000 K), high thermal conductivity (490 W/mK), high atomic displacement threshold (66 eV for Si and 24 eV for C), high breakdown electric field (10³ kV/cm), and excellent charge transport properties make 4H-SiC the next-generation electronic material for harsh environment applications. See, K. C. Mandal, J. W. Kleppinger and S. K. Chaudhuri, “Advances in High-Resolution Radiation Detection Using 4H-SiC Epitaxial Layer Devices,” Micromachines, vol. 11, no. 3, 2020, Art no. 254, doi: 10.3390/mi11030254.

4H-SiC readily forms highly stable Schottky barrier diodes with many metals demonstrating high built-in potential and high minority carrier diffusion length. See, S. K. Chaudhuri, K. J. Zavalla and K. C. Mandal, “High resolution alpha particle detection using 4H-SiC epitaxial layers: Fabrication, characterization, and noise analysis,” Nucl. Instrum. Method Phys. Res. A, vol. 728, pp. 97-101, November 2013, doi: 10.1016/j.nima.2013.06.076, and K. C. Mandal, S. K. Chaudhuri and R. Nag, “High Performance Pd/4H-SiC Epitaxial Schottky Barrier Radiation Detectors for Harsh Environment Applications,” Micromachines, vol. 14, no. 8, 2023, Art. No. 1532, doi: 10.3390/mi14081532. These properties have been tapped in to fabricate nuclear radiation detectors with high charge collection efficiency and excellent energy resolution in self-biased mode. Sec, S. K. Chaudhuri, O. Karadavut, J. W. Kleppinger, R. Nag. G. Yang, D. Lee and K. C. Mandal, “Enhanced Hole Transport in Ni/Y₂O₃/n-4H-SiC MOS for Self-Biased Radiation Detection,” IEEE Electron Dev. Lett., vol. 43, no. 9, pp. 1416-1419, September 2022, doi: 10.1109/LED.2022.3188543.

However, the UV photovoltaic response of present-day low-defect 4H-SiC epitaxial layer and its potential as scintillator detectors has not been explored yet. Ni has been the standard choice as the Schottky contact in 4H-SiC. Molybdenum (Mo), despite its lower work function, has demonstrated higher efficiency, reduced threshold voltage, and lower Ohmic losses. See. G. Lioliou, A. B. Renz. V. A. Shah, P. M. Gammon and A. M. Barnett, “Mo/4H-SiC Schottky diodes for room temperature x-ray and g-ray spectroscopy,” Nucl. Instrum. Methods Phys. Res. A, vol. 1027, March 2022, Art. no. 166330, doi: 10.1016/j.nima.2022.166330. and R. Rupp, R. Elpelt, R. Gerlch, R. Schomer and M. Draghici, “A new SiC diode with significantly reduced threshold voltage,” in 29^{th} International Symposium on Power Semiconductor Devices and IC's (ISPSD), Sapporo, Japan, 2017 pp. 355-358, doi: 10.23919/ISPSD.2017.7988991.

We have demonstrated for the first time the response of self-biased Mo/4H-SiC Schottky diodes as compact ultraviolet photodetector in harsh environment applications where most of the conventional semiconductors fail.

### Experimental Methods

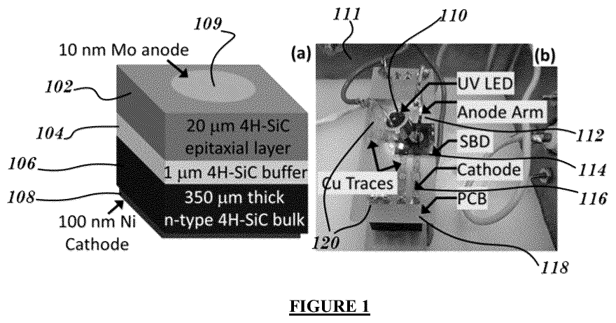

With respect to FIG. 1 at (a), detector grade 20 μm thick n-type 4H-SiC epitaxial layers 102 were grown on the (0001) Si face of a highly conducting (≈0.02 Ω-cm) n-type 4H-SiC substrate 104 by hot-wall chemical vapor deposition. See, J. W. Kleppinger, S. K. Chaudhuri, O. F. Karadavut, R. Nag and K. C. Mandal, “Influence of carrier trapping on radiation detection properties in CVD grown 4H-SiC epitaxial layers with varying thickness up to 250 μm,” J. Cryst. Growth, vol. 583, January 2022, Art. no. 126532, doi: 10.1016/j.jcrysgro.2022.126532. The 350 μm thick substrate surface 106 was 4° off-cut towards the direction to reduce surface defects. The epilayer wafers were diced into 8 mm×8 mm specimens for device fabrication. The specimens were cleaned using a standard RCA procedure followed by removal of the native oxide layer using a 10% diluted aqueous HF solution. See, W. Kern, “The evolution of silicon wafer cleaning technology,” J. Electrochem. Soc., vol. 137, no. 6, pp. 1887-1892, June 1990, doi: 10.1149/1.2086825. Circular shaped (Ø=3.9 mm) thin (10 nm) molybdenum (Mo) contacts 109 were sputter coated on the silicon side of the epilayer 102 to form the Schottky barrier contact. A square (6 mm×6 mm) 80 nm thick nickel was deposited on the bulk side of the 4H-SiC wafer to form the back Ohmic contact 108. An 8 mm×8 mm detector 111 was formed from a UV LED 110, anode arm 112, SBD 114, cathode 116, PCB 118 and copper traces 120.

Alpha spectroscopic measurements were carried out in a benchtop spectrometer with the detectors connected to a CR110 preamplifier and exposed to a 0.9 μCi ²⁴¹Am radioisotope. Sec. O. F. Karadavut, S. K. Chaudhuri, S. K. Kleppinger, R. Nag and K. C. Mandal, “Enhancement of radiation detection performance with reduction of EH_{6/7} deep levels in n-type 4H-SiC through thermal oxidation,” Appl. Phys. Lett, vol. 121, July 2022, Art. no. 012103, doi: 10.1063/5.0089236. The UV response was investigated by recording the current-voltage (I-V) characteristics using a Keithley 237 source-measure unit (SMU) under dark and under illumination when exposed to a Marktech Optoelectronics MT3650N3-UV 1.5 mW ultraviolet (UV) light emitting diode emitting at 365 nm with a spectral line half width of 15 nm.

### Results and Discussion

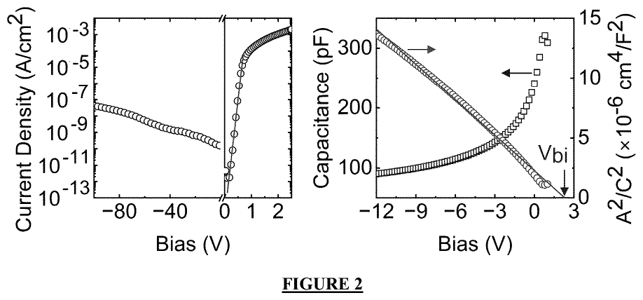

The variation of the dark current density (J) as a function of the forward (positive) and reverse (negative) bias (V) measured at room temperature using the Keithley 237 SMU has been shown in FIG. 2 at (a). The J-V characteristics showed high degree of rectification confirming fabrication of high quality Schottky diodes. The linear region in the forward bias region has been fitted with a thermionic emission model (Eq. 1) which revealed a Schottky barrier height of 1.06 eV and a diode ideality factor of 1.02. Sec. M. J. Tadjer, K. D. Hobart, T. J. Anderson, T. I. Feygelson, R. L. Myers-Ward, A. D. Kochler, F. Calle, C. R. Eddy, D. Kurt Gaskill, B. B. Pate and F. J. Kub, “Thermionic-Field Emission Barrier Between Nanocrystalline Diamond and Epitaxial 4H-SiC,” IEEE Electron. Dev. Lett., vol. 35, no. 12, pp. 1173-1175, October 2014, doi: 10.1109/LED.2014.2364596.

$$J = {A}^{*} {T}^{2} ( {e}^{- {φ}_{B} / {k}_{B} T} ) ( {e}^{\frac{V}{n {k}_{B} T}} - 1 ) \qquad ( 1 )$$

In the above equation A* is the effective Richardson constant (146 Acm⁻²K⁻² for 4H-SiC), φ_{B}—is the Schottky barrier height, n is the diode ideality factor, k_{B} is the Boltzmann constant, and T is the absolute temperature. The observed barrier height is lower than that obtained in our Ni-based SBDs due to the lower work-function of Mo. See, H. B. Michaelson, “The work function of the elements and its periodicity.” J. Appl. Phys., vol. 48, no. 11, pp. 4729-4733, November 1977, doi: 10.1063/1.323539. However, a diode ideality factor close to unity ensures highly uniform spatial barrier height distribution across the Mo contact 109.

FIG. 2 at (b) shows the C-V plot obtained using a capacitance meter that uses a test frequency of 1 MHz. The Mott-Schottky plot is also shown on the right y-axis. A linear fit to the Mott-Schottky plot revealed an effective doping concentration (N_{d}) of 1.15×10¹⁴ cm⁻³ and a built-in potential (V_{bi}) of 2.48 V. Assuming a uniform doping distribution and using the calculated N_{d} and V_{bi} values, the depletion width d at zero bias was calculated to be 4.78 μm using Eq. 1 below.

$$d = \sqrt{\frac{2 {ε}_{4 H - SiC} {ε}_{0}}{q {N}_{e f f}} .} \qquad ( 2 )$$

In the above equation q is the electronic charge, ε₀ is the electrical permittivity of vacuum, and ε_{4H-SiC} is the dielectric constant of 4H-SiC.

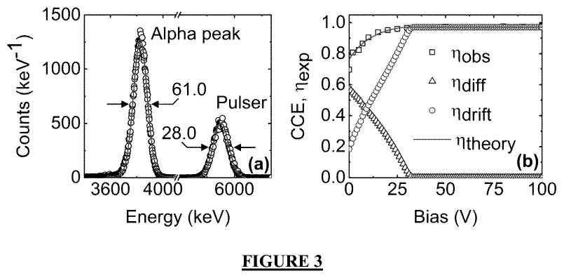

FIG. 3 at (a) shows the pulse height spectrum obtained by the SBD without any applied bias when exposed to the ²⁴¹Am source. A robust peak at 3827 keV (detected energy, E_{α}) corresponding to the 5486 keV alpha particles (incident energy, Eᵢ) with a full width and half maximum (ΔE) of 122 keV implies a very charge collection efficiency (CCE), ηₑₓₚ=(E_{α}/Eᵢ)×100, of ≈70% and a percentage energy resolution ΔEᵣₑₛ=(ΔE/E_{α})×100 of ≈3% in self-biased mode. The energy resolution and the CCE improved with bias as expected. The ηₑₓₚ and ΔEᵣₑₛ at an optimized bias of −50 V were calculated to be ≈98% and ≈0.5%. FIG. 3 at (b) shows the variation of the ηₑₓₚ as a function of the applied reverse bias which has been fitted to the drift-diffusion model. See, M. B. H. Breese, “A theory of ion beam induced charge collection,” J. Appl. Phys., vol. 74, no. 6, pp. 3789-3799, June 1993, doi: 10.1063/1.354471.

$${η}_{theory} = \frac{1}{{E}_{α}} {\int }_{0}^{{x}_{d}} ( \frac{dE}{dx} ) dx + {\int }_{{x}_{d}}^{{x}_{r}} ( \frac{dE}{dx} ) exp [ - \frac{x - {x}_{d}}{{L}_{d}} ] dx = {η}_{drift} + {η}_{diff} . \qquad ( 3 )$$

In the above equation, η_{theory} is the theoretical CCE, dE/dx is the stopping power of 5486-keV alpha particles in 4H-SiC, x_{d} is the depletion width at a given bias, xᵣ is the range of the alpha particles and x is the distance within the 4H-SiC epilayer. The first term on right is the CCE in the depletion region due to the drift (η_{drif}t) and the second term is due to the diffusion in the neutral region (η_{diff}) of the charge carriers. The minority carrier (hole) diffusion length L_{d}, calculated to be 22.8 μm from the fitting, is high enough for most of the holes generated by the incident alpha particles in the neutral region to reach the edge of the depletion width, from where they drift under the action of the built-in potential and are collected by the anode. The high values of L_{d} and V_{bi} resulted in the observed high CCE and energy resolution in self-biased mode. Such superior self-biased performance is highly sought-after in space missions where conventional and solar power supplies are not an option and are also the fundamental requirement of photovoltaic cells.

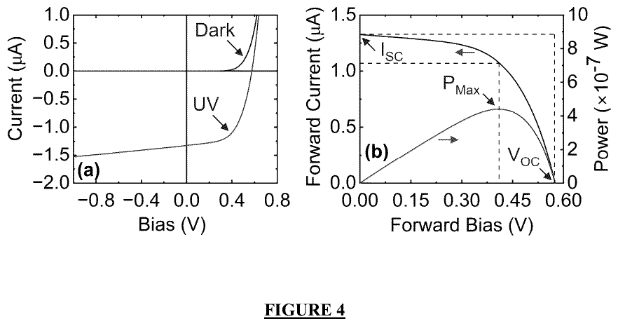

Being a wide bandgap semiconductor, 4H-SiC is highly efficient in absorbing UV rays making it a suitable candidate for UV detectors. FIG. 4 at (a) shows the variation of dark and the UV illuminated current as a function of applied bias. The ratio of the illuminated to dark current at 0 V applied bias was found to be 7×10⁵ for a 1.5 mW LED emitting at 365 nm. The open-circuit voltage V_{OC} and the short circuit I_{SC} current calculated from the absolute forward I-V characteristics shown in FIG. 4 at (b) was 0.58 V and 1.33 μA, respectively. Sec, S. Das, S. K. Chaudhuri, R. N. Bhattacharya and K. C. Mandal, “Defect levels in Cu₂ZnSn(SₓSe₁₋ₓ)₄ solar cells probed by current-mode deep level transient spectroscopy.” Appl. Phys. Lett., vol. 104, May 2014, Art. no. 192106, doi: 10.1063/1.4876925. The fill factor, FF calculated as P_{Max}/(I_{SC})×V_{OC} was found to be 0.57, where P_{Max}, the maximum output power is calculated to be 0.44 μW. The penetration depth of 365 nm photons in 4H-SiC is ˜100 μm, which suggests that a major fraction of the photogenerated charge carriers were in the neutral region of the epilayer of the self-biased detector. S. G. Sridhara, R. P. Devaty and W. J. Choyke, “Absorption coefficient of 4H silicon carbide from 3900 to 3250 Å,” J. Appl. Phys., vol. 84, no. 5, pp. 2963-2964, September 1998, doi: 10.1063/1.368403. Hence, the long hole diffusion length was instrumental in achieving such high performance in the photovoltaic mode.

### CONCLUSION

Properties conducive to efficient UV photovoltaic operation in harsh environment has been observed in Mo/n-4H-SiC epitaxial SBDs. The low defect and highly crystalline detector grade epilayers demonstrated a hole diffusion length >20 μm and built-in potential of 2.48 V that enabled a 70% charge collection efficiency at 0 V applied bias when an SBD was exposed to 5486 keV alpha particles. Such high built-in potential and diffusion length led to a very high photocurrent gain of 7×10⁵ in self-biased mode when the SBD was exposed to a 1.5 mW LED emitting at 365 nm. A maximum power output of 4.4 μW and a fill factor of 0.57 was measured in the photovoltaic mode. The findings presented in this letter implies that such robust, compact, radiation hard, and high-temperature 4H-SiC self-biased UV detector is poised to bridge the technological gap in application of x-/γ-ray scintillators in extreme harsh environments including space missions, medical imaging, nuclear non-proliferation, and homeland security.

The current disclosure provides novel self-biased devices which addresses practical challenges in field applications with high technological importance. The results will open new research avenues in nuclear security, non-proliferation, high-energy physics research, medical imaging etc.

Various modifications and variations of the described methods, elemental compositions, and kits of the disclosure will be apparent to those skilled in the art without departing from the scope and spirit of the disclosure. Although the disclosure has been described in connection with specific embodiments, it will be understood that it is capable of further modifications and that the disclosure as claimed should not be unduly limited to such specific embodiments. Indeed, various modifications of the described modes for carrying out the disclosure that are obvious to those skilled in the art are intended to be within the scope of the disclosure. This application is intended to cover any variations, uses, or adaptations of the disclosure following, in general, the principles of the disclosure and including such departures from the present disclosure come within known customary practice within the art to which the disclosure pertains and may be applied to the essential features herein before set forth.

What is claimed is:

1. A vertical Schottky diode comprising:
at least one semi-transparent metal anode contact;
wherein the at least one semi-transparent metal anode contact is deposited on at least one silicon face of at least one n-type 4H-SiC epilayer;
at least one 4H-SiC buffer layer affixed to the at least one n-type 4H-SiC epilayer;
at least one n-type 4H-SiC bulk layer affixed to the at least one 4H-SiC buffer layer;
at least one cathode affixed to the at least one 4H-SiC buffer layer on a side opposite the at least one n-type 4H-SiC bulk layer.

2. The vertical Schottky diode of claim 1, wherein the effective doping concentration of the at least one semi-transparent metal anode contact deposited on the at least one n-type 4H-SiC epilayer is 10\hat{ }¹⁴ cm\hat{ }⁻³.

3. The vertical Schottky diode of claim 1, wherein the at least one n-type 4H-SiC epilayer is substantially 20 μm in thickness.

4. The vertical Schottky diode of claim 1, wherein the vertical Schottky diode is incorporated into at least one self-biased ultraviolet photovoltaic cell.

5. The vertical Schottky diode of claim 1, wherein the vertical Schottky diode is incorporated into at least one self-powered ultraviolet sensor.

6. The vertical Schottky diode of claim 5, wherein the at least one self-powered ultraviolet sensor is incorporated into at least one nuclear reactor or at least one space craft.

7. The vertical Schottky diode of claim 1, wherein the vertical Schottky diode has a built-in voltage of 2.48 V measured from capacitance-voltage characteristics with a test frequency of 1 MHz.

8. The vertical Schottky diode of claim 1, wherein the vertical Schottky diode has a hole diffusion length of 22.8 μm calculated using a drift-diffusion model applied to alpha radiation response of the vertical Schottky.

9. The vertical Schottky diode of claim 1, wherein the vertical Schottky diode has a charge collection efficiency of substantially 70% when exposed to 5486 keV alpha particles and a current gain at 0 V applied bias.

10. The vertical Schottky diode of claim 1, wherein at least one semi-transparent metal anode contact comprises molybdenum and the at least one cathode comprises nickel.

11. A method for making a vertical Schottky diode comprising:
depositing, via hot-wall chemical vapor deposition, at least one semi-transparent metal anode onto at least one silicon face of at least one n-type 4H-SiC epitaxial layer;
forming at least one 4H-SiC buffer layer attached to the at least one n-type 4H-SiC epitaxial layer;
forming at least one n-type 4H-SiC bulk layer attached to the at least one 4H-SiC buffer layer; and
forming at least one cathode affixed to a side of the n-type 4H-SiC bulk layer opposite the at least one n-type 4H-SiC buffer layer.

12. The method for making a vertical Schottky diode claim 11, wherein the effective doping concentration of the at least one semi-transparent metal anode contact deposited on the at least one n-type 4H-SiC epitaxial layer is 10\hat{ }¹⁴ cm\hat{ }⁻³.

13. The method for making a vertical Schottky diode of claim 11, wherein the at least one n-type 4H-SiC epitaxial is substantially 20 μm in thickness.

14. The method for making a vertical Schottky diode of claim 11, further comprising incorporating the vertical Schottky diode into at least one self-biased ultraviolet photovoltaic cell.

15. The method for making a vertical Schottky diode of claim 11, further comprising incorporating the vertical Schottky diode into at least one self-powered ultraviolet sensor.

16. The method for making a vertical Schottky diode of claim 15, further comprising incorporating the at least one self-powered ultraviolet sensor into at least one nuclear reactor or at least one space craft.

17. The method for making a vertical Schottky diode of claim 11, further comprising configuring the vertical Schottky diode to have a built-in voltage of 2.48 V measured from capacitance-voltage characteristics with a test frequency of 1 MHz.

18. The method for making a vertical Schottky diode of claim 11, further comprising configuring the vertical Schottky diode to have a hole diffusion length of 22.8 μm calculated using a drift-diffusion model applied to alpha radiation response of the vertical Schottky.

19. The method for making a vertical Schottky diode of claim 11, further comprising configuring the vertical Schottky diode to have a charge collection efficiency of substantially 70% when exposed to 5486 keV alpha particles and a current gain at 0 V applied bias.

20. The method for making a vertical Schottky diode of claim 11, further comprising configuring the at least one semi-transparent metal anode contact to comprise molybdenum and configuring the at least one cathode to comprise nickel.
